(19) United States
(12) Patent Application Publication
(10) Pub. No.: US 2016/0240558 A1
(43) Pub. Date: Aug. 18, 2016

(54) MANUFACTURING METHOD FOR ARRAY SUBSTRATE, ARRAY SUBSTRATE AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Zhixiang ZOU, Beijing (CN); Chengshao YANG, Beijing (CN); Yinhu HUANG, Beijing (CN)

(21) Appl. No.: 14/906,461

(22) PCT Filed: Aug. 18, 2015
(86) PCT No.: PCT/CN2015/087337

§ 371 Date: Jan. 20, 2016

(30) Foreign Application Priority Data
Feb. 12, 2015 (CN) 201510076792.5

(51) Int. Cl. H01L 27/12; H01L 21/027

(52) U.S. Cl. CPC H01L 27/124; H01L 27/1262; H01L 27/127; H01L 21/0274; H01L 27/1222

(57) ABSTRACT

A manufacturing method comprises steps of: forming a metal pattern having a thickness d on a substrate; forming an insulating film layer on the substrate on which the metal pattern is formed, so that the insulating film layer has an overlap region with the metal pattern, an absolute value of a height difference between the overlap region of the insulating film layer and other regions of the insulating film layer being less than the thickness d; and, forming a pattern of a semiconductor layer and a source/drain metal layer on the substrate on which the insulating film layer is formed.

### FIELD OF THE INVENTION

The present invention relates to the field of display technology, and in particular relates to a manufacturing method for an array substrate, an array substrate and a display device.

### BACKGROUND OF THE INVENTION

As one important component of a display device, an array substrate generally includes a substrate, and gate lines, common electrode wiring, an insulating film layer, a semiconductor layer, a source/drain metal layer (sources/drains and data lines) and the like on the substrate.

In the prior art, during manufacturing an array substrate, firstly a metal pattern (e.g., a pattern of gate lines) is formed on a substrate, subsequently an insulating film layer is then coated on the substrate on which the metal pattern is formed, and then a pattern of a semiconductor layer and a source/drain metal layer is formed on the substrate coated with the insulating film layer, wherein the insulating film layer has an overlap region of the insulating film layer with the metal pattern (the overlap region refers to a protection region of the metal pattern on the insulating film layer). The overlap region of the insulating film layer with the metal pattern on the insulating film layer is also called an overlap region of the insulating film layer. The overlap region of the insulating film layer is formed with protrusions, and other patterns (sources/drains and data lines) subsequently formed on the insulating film layer will also generate corresponding protrusions (protrusions of the sources/drains, and protrusions of the data lines).

In the above method, when the metal pattern is relatively thick, the protrusion of other patterns (e.g., patterns of sources/drains) formed on the overlap region of the insulating film layer will be relatively high, so it is likely to result in line breakage and thus degrade a rate of qualified product.

### SUMMARY OF THE INVENTION

According to a first aspect of the present invention, a manufacturing method for an array substrate is provided. The manufacturing method includes steps of:

forming a metal pattern having a thickness d on a substrate;

forming an insulating film layer on the substrate on which the metal pattern is formed so that the insulating film layer has an overlap region with the metal pattern, the absolute value of a height difference between the overlap region of the insulating film layer and other regions of the insulating film layer being less than the thickness d; and

forming a pattern of a semiconductor layer and a source/drain metal layer on the substrate on which the insulating film layer is formed.

Alternatively, the step of forming a metal pattern having a thickness d on a substrate includes steps of:

forming a groove on the substrate; and

forming the metal pattern having the thickness d in the groove.

Alternatively, the step of forming an insulating film layer on the substrate on which the metal pattern is formed includes steps of:

forming an initial insulating film layer on the substrate on which the metal pattern is formed, wherein an overlap region of the initial insulating film layer with the metal pattern is protruded from the initial insulating film layer; and

thinning the overlap region of the initial insulating film layer to obtain the insulating film layer so that the absolute value of the height difference between the overlap region of the insulating film layer and other regions of the insulating film layer is less than the thickness d.

Alternatively, the step of thinning the overlap region includes step of:

processing the overlap region of the initial insulating film layer by a single patterning process so that the absolute value of the height difference between the overlap region of the processed initial insulating film layer and other regions of the processed initial insulating film layer is less than the thickness d.

Alternatively, the step of forming an insulating film layer on the substrate on which the metal pattern is formed includes steps of:

forming an organic film layer on the substrate on which the metal pattern is formed, wherein the organic film layer has an overlap region with the metal pattern, and the overlap region of the organic film layer is protruded from the organic film layer;

thinning the overlap region of the organic film layer so that the absolute value of the height difference between the overlap region of the processed organic film layer and other regions of the processed organic film layer is less than the thickness d; and

forming the insulating film layer on the substrate on which the organic film layer is formed;

or,

forming an insulating organic film layer on the substrate on which the metal pattern is formed, wherein the organic film layer has an overlap region with the metal pattern, and the overlap region of the organic film layer is protruded from the organic film layer; and

thinning the overlap region of the organic film layer so that the absolute value of the height difference between the overlap region of the processed organic film layer and other regions of the processed organic film layer is less than the thickness d.

Alternatively, the step of thinning the overlap region of the organic film layer includes step of:

performing an exposure and development process on the overlap region of the organic film layer so that the absolute value of the height difference between the overlap region of the processed organic film layer and other regions of the processed organic film layer is less than the thickness d.

Alternatively, the step of forming an insulating layer on the substrate on which the metal pattern is formed includes steps of:

forming a reverse pattern on the substrate on which the metal pattern is formed, so that the reverse pattern is provided within a region without the metal pattern on the substrate, the reverse pattern being formed from an insulating material; and

forming the insulating film layer on the substrate on which the reverse pattern is formed, so that the insulating film layer has an overlap region with the metal pattern, the absolute value of the height difference between the overlap region of the insulating film layer and other regions of the insulating film layer being less than the thickness d.

Alternatively, the insulating material is an organic material.

As an alternative, the step of forming the insulating film layer on the substrate on which the reverse pattern is formed may include steps of: forming an initial insulating film layer on the substrate on which the reverse pattern is formed, wherein an overlap region of the initial insulating film layer with the metal pattern is protruded from the initial insulating film layer; and thinning the overlap region of the initial insulating film layer to obtain the insulating film layer so that the absolute value of the height difference between the overlap region of the insulating film layer and other regions of the insulating film layer is less than the thickness d. The step of thinning the overlap region may include step of: processing the overlap region of the initial insulating film layer by a single patterning process so that the absolute value of the height difference between the overlap region of the processed initial insulating film layer and other regions of the processed initial insulating film layer is less than the thickness d.

As another alternative, the step of forming an insulating film layer on the substrate on which the reverse pattern is formed may include steps of: forming an organic film layer on the substrate on which the reverse pattern is formed, wherein the organic film layer has an overlap region with the metal pattern, and the overlap region of the organic film layer is protruded from the organic film layer; thinning the overlap region of the organic film layer so that the absolute value of the height difference between the overlap region of the processed organic film layer and other regions of the processed organic film layer is less than the thickness d; and forming the insulating film layer on the substrate on which the organic film layer is formed; or, forming an insulating organic film layer on the substrate on which the reverse pattern is formed, wherein the organic film layer has an overlap region with the metal pattern, and the overlap region of the organic film layer is protruded from the organic film layer; and thinning the overlap region of the organic film layer so that the absolute value of the height difference between the overlap region of the processed organic film layer and other regions of the processed organic film layer is less than the thickness d. The step of thinning the overlap region of the organic film layer may include step of: performing an exposure and development process on the overlap region of the organic film layer so that the absolute value of the height difference between the overlap region of the processed organic film layer and other regions of the processed organic film layer is less than the thickness d.

Alternatively, the metal pattern is a pattern including gate lines or a pattern including gate lines and common electrode wiring.

Alternatively, the height difference between the overlap region of the insulating film layer and the other regions of the insulating film layer is 0.

According to a second aspect of the present invention, an array substrate is provided, including:

a substrate;

a metal pattern having a thickness d formed on the substrate;

an insulating film layer formed on the substrate on which the metal pattern is formed, wherein the insulating film layer has an overlap region with the metal pattern, and an absolute value of a height difference between the overlap region of the insulating film layer and other regions of the insulating film layer is less than the thickness d; and

a pattern of a semiconductor layer and a source/drain metal layer formed on the insulating film layer.

Alternatively, the array substrate further includes: a groove formed on the substrate, wherein the metal pattern having a thickness d is arranged in the groove.

Alternatively, the array substrate further includes: an organic film layer formed between the insulating film layer and the metal pattern, wherein the organic film layer has an overlap region with the metal pattern.

Alternatively, the insulating film layer is an organic insulating film layer.

Alternatively, the array substrate further includes: a reverse pattern formed within a region without the metal pattern on the substrate, beneath the insulating film layer, wherein the reverse pattern is made from an insulating material.

Alternatively, the insulating material is an organic material.

Alternatively, the metal pattern is a pattern including gate lines or a pattern including gate lines and common electrode wiring.

Alternatively, the height difference between the overlap region of the insulating film layer and other regions of the insulating film layer is 0.

According to a third aspect of the present invention, a display device is provided, including one of the various array substrates provided by the second aspect.

The technical solutions provided by the present invention may achieve the following beneficial effects:

by controlling the absolute value of the height difference between the overlap region of the insulating film layer and other regions of the insulating film layer to be less than the thickness d, the unevenness of other patterns subsequently formed on the substrate on which the insulating film layer is formed is correspondingly reduced, so that the effects of reducing the breakage possibility of a wiring formed on the insulating film layer and improving a rate of qualified product can be achieved.

It should be understood that the above general description and the detailed description below are merely exemplary and explanatory, and not intended to limit the present invention.

### BRIEF DESCRIPTION OF THE DRAWINGS

The accompanying drawings herein are incorporated into this specification and constitute a part of this specification. Embodiments conforming to the present invention are shown, and together with this specification, used for illustrating the principle of the present invention.

FIG. 1 is a flowchart showing a manufacturing method for an array substrate according to an exemplary embodiment;

FIG. 2 is a flowchart showing a manufacturing method for an array substrate according to another exemplary embodiment;

FIGS. 3, 4, 5, 6A and 6B are schematic diagrams of structures formed by the steps of the manufacturing method shown in FIG. 2;

FIG. 7 is a flowchart showing a manufacturing method for an array substrate according to another exemplary embodiment;

FIGS. 8, 9, 10 and 11 are schematic diagrams of structures formed by the steps of the manufacturing method shown in FIG. 7;

FIG. 12 is a flowchart showing a manufacturing method for an array substrate according to another exemplary embodiment;

FIGS. 13, 14A and 14B are schematic diagrams of structures formed by the steps of the manufacturing method shown in FIG. 12;

FIG. 15 is a flowchart showing a manufacturing method for an array substrate according to another exemplary embodiment;

FIGS. 16, 17, 18A and 18B are schematic diagrams of structures formed by the steps of the manufacturing method shown in FIG. 15;

FIG. 19A and FIG. 19B are comparative diagrams of the array substrate provided by the embodiments of the present invention and the array substrate of the prior art;

FIG. 20 is a flowchart showing a manufacturing method for an array substrate according to another exemplary embodiment;

FIG. 21 is a structural diagram showing an array substrate according to an exemplary embodiment; and

FIG. 22 is a block diagram showing a display device according to an exemplary embodiment.

The specific embodiments of the present invention are showed in the accompanying drawings, and will be described in more detail hereinafter. These accompanying drawings and the literal description are not intended to limit the scope of the inventive concept in any way, but explaining the concept of the present invention to those skilled in the art with reference to the specific embodiments.

### DESCRIPTION OF THE PREFERRED EMBODIMENTS

The exemplary embodiments will be described in detail, and examples thereof are shown in the accompanying drawings. When the following description involves the accompanying drawings, like reference numerals in different accompanying drawings denote like or similar elements, unless indicated otherwise. The implementations described in the following exemplary embodiments do not represent all implementations consistent with the present invention. Conversely, these are merely examples of the devices and methods which are described in detail in the appended claims and are consistent with some aspects of the present invention.

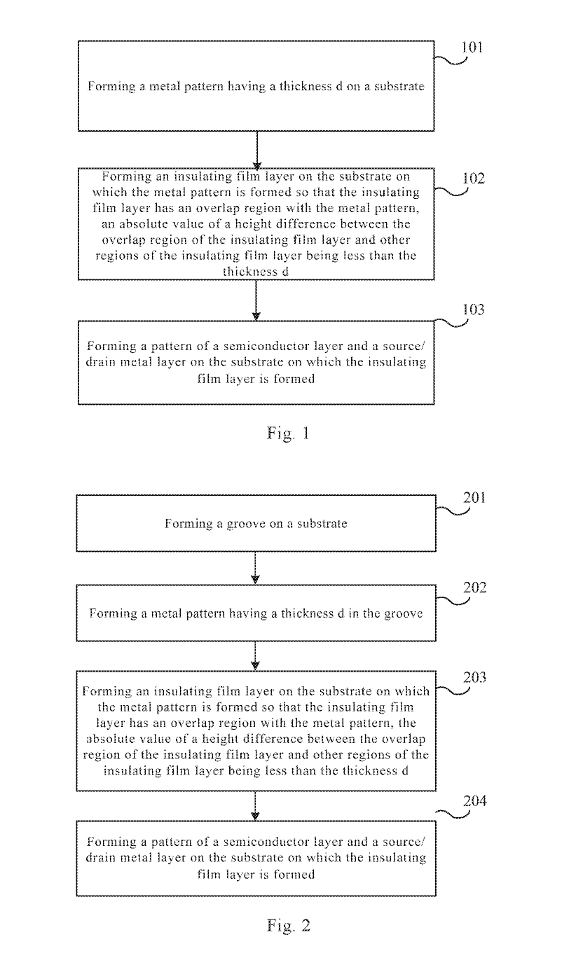

FIG. 1 is a flowchart showing a manufacturing method for an array substrate according to an exemplary embodiment. The manufacturing method for an array substrate may include the following steps:

Step 101: A metal pattern having a thickness d is formed on a substrate.

For example, the metal pattern is a pattern including gate lines; or, the metal patter is a pattern including gate lines and common electrode wiring.

Step 102: An insulating film layer is formed on the substrate on which the metal pattern is formed, so that the insulating film layer has an overlap region with the metal pattern, the absolute value of a height difference between the overlap region of the insulating film layer and other regions of the insulating film layer being less than the thickness d.

Step 103: A pattern of a semiconductor layer and a source/drain metal layer is formed on the substrate on which the insulating layer is formed.

In conclusion, in the manufacturing method for an array substrate provided by this embodiment, by controlling the absolute value of the height difference between the overlap region of the insulating film layer and other regions of the insulating film layer to be less than the thickness d, the unevenness of other patterns subsequently formed on the substrate on which the insulating film layer is formed is correspondingly reduced, so that the effects of reducing the breakage possibility of a wiring formed on the insulating film layer and improving a rate of qualified product can be achieved.

Four embodiments will be described below according to four solutions for reducing the height difference between the overlap region of the insulating film layer and other regions of the insulating film layer.

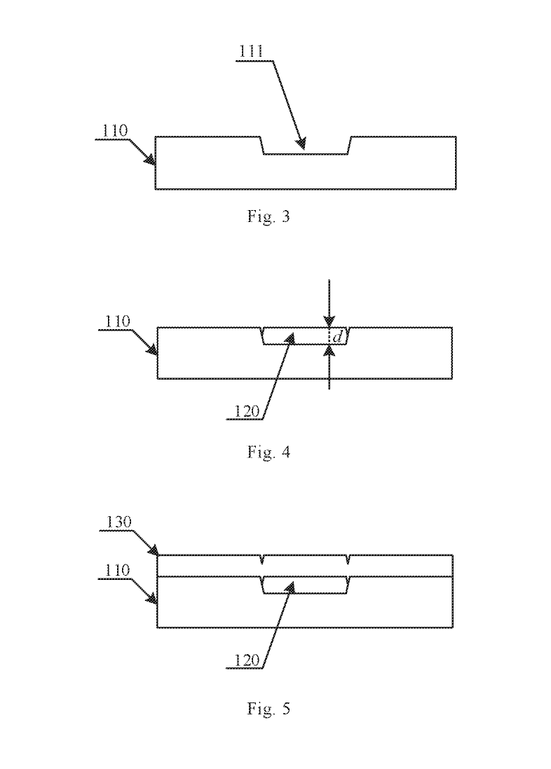

FIG. 2 is a flowchart showing a manufacturing method for an array substrate according to another exemplary embodiment. The manufacturing method for an array substrate may include the following steps.

S201: A groove is formed on a substrate.

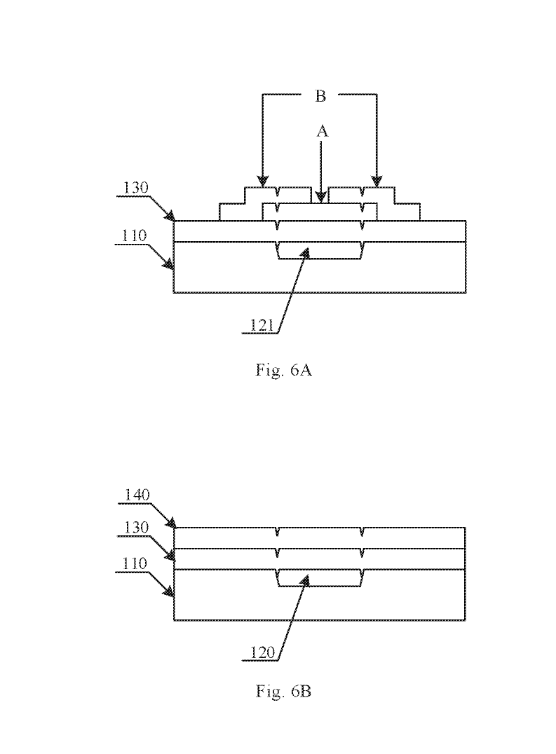

During manufacturing an array substrate, a groove may be formed on a substrate first. The pattern of the groove may be the same as the metal pattern. The substrate may be a glass substrate or other transparent substrate. FIG. 3 is a structural diagram of a substrate 110 on which a groove 111 is formed.

It is to be noted that the groove may be formed on the glass substrate by a single patterning process. It is to be noted that the single patterning process may generally include: coating photoresist, exposure, developing, etching, photoresist stripping or other process. For example, the process of forming a groove on a substrate by a single patterning process may include: coating negative photoresist having a thickness of 1.0 μm to 3.0 μm on a substrate, forming a gate pattern by exposure through a gate mask plate, then controlling the depth of the groove by adjusting the time of etching, and finally stripping the negative photoresist.

Step 202: A metal pattern having a thickness d is formed in the groove.

The metal pattern having a thickness d is formed in the groove by a patterning process. For example, 0.1 μm≦d≦0.4 μm. The metal pattern may be a pattern including gate lines, or a pattern including gate lines and common electrode wiring. The metal pattern may be formed from Al, Cu, Mo or other metal. It is to be noted that the metal pattern is generally a pattern including gate lines only; however, when it is required to use a metal electrode to improve the resistance homogenization of common electrodes, it is possible to provide additional metal wiring which are called common electrode wiring and located in a same layer as the gate lines. A pattern including gate lines and common electrode wiring may be formed by a single patterning process.

FIG. 4 is a structural diagram of the substrate 110 with the metal pattern 120 formed in the groove, wherein the metal pattern 120 is formed in the groove 111 (not shown in FIG. 4) on the substrate 110. FIG. 4 shows a case where the depth of the groove is equal to the thickness d of the metal pattern 120. In comparison to the prior art, the formation of the metal pattern in the groove may effectively reduce a height difference between a region formed with the metal pattern and other regions without the metal pattern, thereby reducing the height difference between the subsequently formed a pattern of a semiconductor layer and a source/drain metal layer in the overlap region of the insulating film layer and that in other regions of the insulating film layer.

It is to be noted that the height in each embodiment of the present invention is benchmarked against the lower surface of the substrate, unless otherwise specified.

Step 203: An insulating film layer is formed on the substrate on which the metal pattern is formed, so that the insulating film layer has an overlap region with the metal pattern, the absolute value of a height difference between the overlap region of the insulating film layer and other regions of the insulating film layer being less than the thickness d.

After the metal pattern is formed on the substrate, an insulating film layer may be formed on the substrate. The insulating film layer may be formed from SiNx, SiO₂, Al₂O₃ or other material. FIG. 5 is a structural diagram of the substrate 110 with the insulating film layer 130 being formed on the metal pattern 120.

It is to be noted that, after the insulating film layer is formed, the shape of the upper surface generally depends on the shape of a surface covered by the lower surface of the insulating film layer. Accordingly, in comparison to the prior art, the formation of the metal pattern in the groove on the substrate reduces the height difference between a region formed with the metal pattern on the substrate and other regions without the metal pattern, so that the absolute value of the height difference between the overlap region of the insulating film layer and other regions of the insulating film layer is less than the thickness d.

It is to be noted that, when the depth of the groove is equal to the thickness d, the height difference between the overlap region of the insulating film layer and other regions of the insulating film layer may be considered to be 0. In this case, the influences of the metal pattern on sources/drains may be fundamentally eliminated.

Step 204: A pattern of a semiconductor layer and a source/drain metal layer is formed on the substrate on which the insulating film layer is formed.

After the insulating film layer is formed, a pattern of a semiconductor layer and a source/drain metal layer may be formed on the substrate, and other subsequent processes may be performed to the substrate. For the subsequent processes, reference may be specifically made to the prior art as required and they will not be described in detail here. As the absolute value of the height difference between the overlap region of the insulating film layer and other regions of the insulating film layer is less than the thickness d, protrusions on the insulating film layer 130 are relatively small, so that the protrusions of sources/drains and the protrusions of data lines may be reduced in the embodiment of the present invention. The structure of the sources/drains on the substrate is as shown in FIG. 6A. FIG. 6A is structural diagram of the substrate 110 with a pattern B including a semiconductor layer A and sources/drains being formed on the insulating film layer 130, wherein the metal pattern is gate lines 121, and the structure of data lines on the substrate is as shown in FIG. 6B. FIG. 6B is a structural diagram of the substrate 110 with data lines 140 being formed on the insulating film layer 130, wherein the metal pattern 120 is formed on the substrate 110.

In conclusion, in the manufacturing method for an array substrate provided by this embodiment, by controlling the absolute value of the height difference between the overlap region of the insulating film layer and other regions of the insulating film layer to be less than the thickness d, the unevenness of other patterns subsequently formed on the substrate on which the insulating film layer is formed is correspondingly reduced, so that the effects of reducing the breakage possibility of a wiring formed on the insulating film layer and improving a rate of qualified product can be achieved.

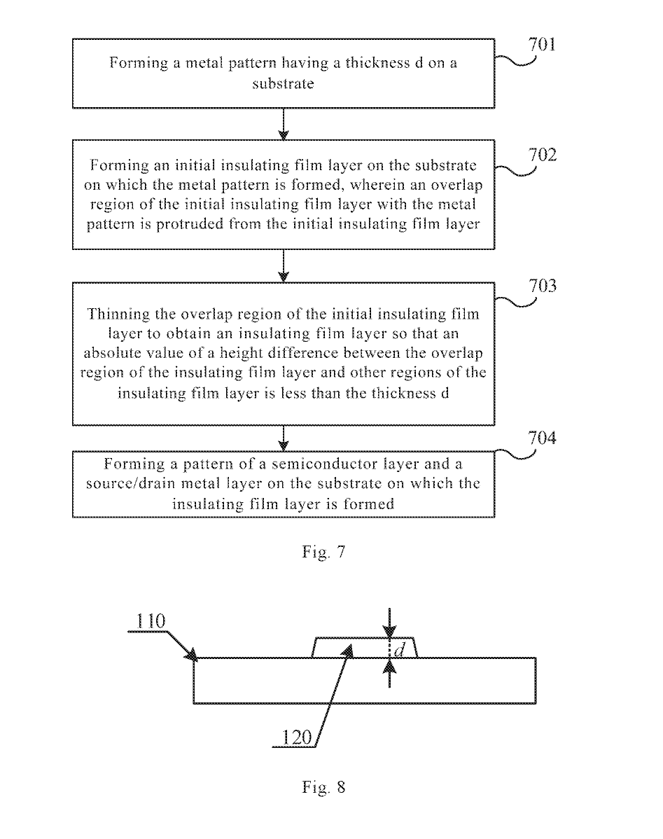

FIG. 7 is a flowchart showing a manufacturing method for an array substrate according to another exemplary embodiment. The manufacturing method for an array substrate may include the following steps.

Step 701: A metal pattern having a thickness d is formed on a substrate.

During manufacturing an array substrate, a metal pattern having a thickness d may be first formed on a substrate by a single patterning process. For example, 0.1 μm≦d≦0.4 μm. The metal pattern may be a pattern of gate lines, or a pattern of gate lines and common electrode wiring. The metal pattern may be formed from Al, Cu, Mo or other metal.

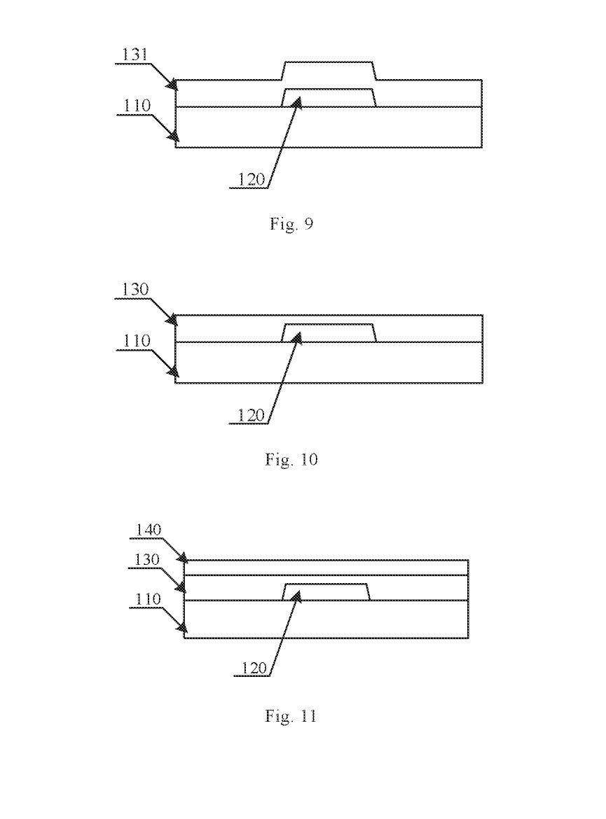

It is to be noted that the metal pattern is generally a pattern including gate lines only; however, when it is required to use a metal electrode to improve the resistance homogenization of common electrodes, it is possible to provide additional metal wiring which are called common electrode wiring and located in a same layer as the gate lines, and a pattern of gate lines and common electrode wiring may be formed by a single patterning process. The substrate may be a glass substrate or other transparent substrate. FIG. 8 is a structural diagram of the substrate 110 on which the metal pattern 120 having a thickness d is formed.

Step 702: An initial insulating film layer is formed on the substrate on which the metal pattern is formed, wherein an overlap region of the initial insulating film layer with the metal pattern is protruded from the initial insulating film layer.

After the metal pattern is formed on the substrate, an initial insulating film layer may be formed on the substrate. An overlap region of the initial insulating film layer with the metal pattern is protruded from the initial insulating film layer. The initial insulating film layer may be formed from SiNx, SiO2, Al2O3 or other material. FIG. 9 is a structural diagram of the substrate 110 on which the initial insulating film layer 131 is formed, wherein the metal pattern 120 is formed on the substrate 110.

Step 703: The overlap region of the initial insulating film layer is thinned to obtain an insulating film layer, so that an absolute value of a height difference between an overlap region of the insulating film layer and other regions of the insulating film layer is less than the thickness d.

After the initial insulating film layer is formed on the substrate, the overlap region of the initial insulating film layer may be thinned to obtain an insulating film layer, so that an absolute value of a height difference between an overlap region of the insulating film layer and other regions of the insulating film layer is less than the thickness d. FIG. 10 is a structural diagram of the substrate 110 after the overlap region of the initial insulating film layer is thinned to obtain the insulating film layer 130, wherein the metal pattern 120 is formed on the substrate 110.

For example, the overlap region of the initial insulating film layer may be processed by a single patterning process so that the absolute value of the height difference between the overlap region of the processed initial insulating film layer and other regions of the initial insulating film layer is less than the thickness d. Specifically, the height difference between the overlap region of the initial insulating film layer and other regions of the initial insulating film layer may be controlled by controlling the time of etching. Alternatively, when the thickness of the initial insulating film layer is greater than the thickness d, the height difference between the processed overlap region of the insulating film layer and other regions of the insulating film layer may be 0.

It is to be noted that, to prevent the damage to the structural performance of thin film transistors (TFTs), an overlap region of sources/drains with the initial insulating film layer is generally not thinned. Therefore, in this embodiment, the overlap region of the initial insulating film layer generally refers to an overlap region of the structure of data lines with the initial insulating film layer.

Step 704: A pattern of a semiconductor layer and a source/drain metal layer is formed on the substrate on which the insulating film layer is formed.

After the insulating film layer is formed, a pattern of a semiconductor layer and a source/drain metal layer may be formed on the substrate, and then other subsequent processes are performed to the substrate. For the subsequent processes, reference may be specifically made to the prior art as required and they will not be described in detail here. The structure of data lines on the substrate is as shown in FIG. 11. FIG. 11 is a structural diagram of the substrate 110 with data lines 140 being formed on the insulating film layer 130, wherein the metal pattern 120 is formed on the substrate 110.

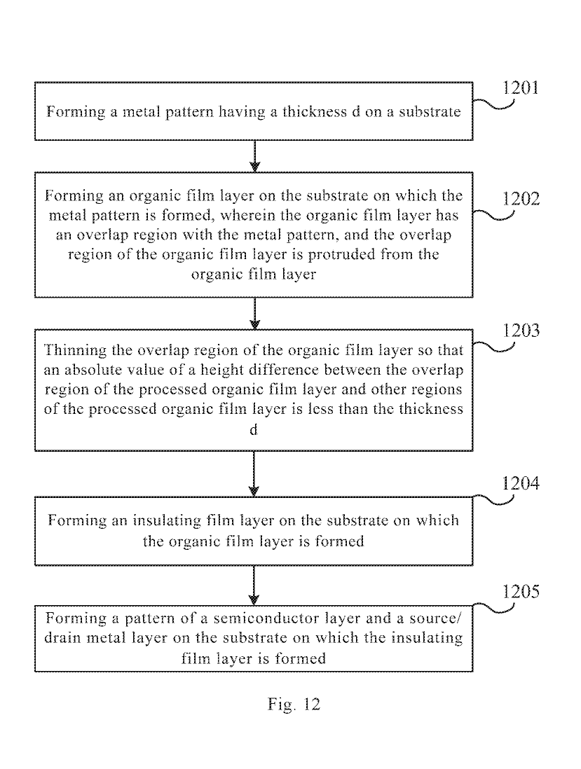

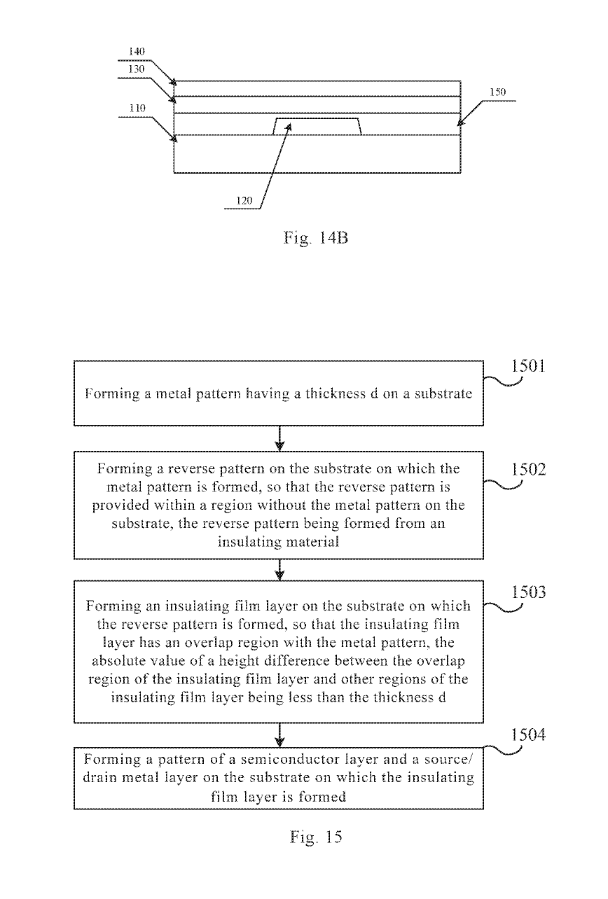

It is to be noted that, the manufacturing method for an array substrate shown in FIG. 7 is generally applied to the reduction of protrusions of data lines; however, when it is required to reduce the protrusions of sources/drains, to ensure the structural performance of TFTs, the manufacturing method for an array substrate provided by the embodiment shown in FIG. 2, FIG. 12 or FIG. 15 in the present invention is generally utilized.

In conclusion, in the manufacturing method for an array substrate provided by this embodiment, by controlling the absolute value of the height difference between the overlap region of the insulating film layer and other regions of the insulating film layer to be less than the thickness d, the unevenness of other patterns subsequently formed on the substrate on which the insulating film layer is formed is correspondingly reduced, so that the effects of reducing the breakage possibility of a wiring formed on the insulating film layer and improving a rate of qualified product can be achieved.

FIG. 12 is a flowchart showing a manufacturing method for an array substrate according to another exemplary embodiment. The manufacturing method for an array substrate may include the following steps.

Step 1201: A metal pattern having a thickness d is formed on a substrate.

During manufacturing an array substrate, a metal pattern having a thickness d may be first formed on a substrate by a single patterning process. For example, 0.1 μm≦d≦0.4 μm. The metal pattern may be a pattern of gate lines, or a pattern of gate lines and common electrode wiring. The metal pattern may be formed from Al, Cu, Mo or other metal. The substrate may be a glass substrate or other transparent substrates. Reference may be made to FIG. 8 for the structure of the substrate 110 at the end of step 1201.

It is to be noted that the metal pattern is generally a pattern including gate lines only; however, when it is required to use a metal electrode to improve the resistance homogenization of common electrodes, it is possible to provide additional metal wiring which are called common electrode wiring and located in a same layer as the gate lines, and a pattern of gate lines and common electrode wiring may be formed by a single patterning process.

Step 1202: An organic film layer is formed on the substrate on which the metal pattern is formed, wherein the organic film layer has an overlap region with the metal pattern, and the overlap region of the organic film layer is protruded from the organic film layer.

After the metal pattern is formed on the substrate, an organic film layer may be formed on the substrate. An overlap region (the overlap region, also called an overlap region of the organic film layer, refers to a projection region on the organic film layer) of the organic film layer with the metal pattern is protruded from the organic film layer. The organic film layer may be formed from an insulating organic film material which can be photo-etched. Reference may be made to FIG. 9 for the structure of the substrate 110 at the end of step 1202. At this time, the initial insulating film layer 131 in FIG. 9 is replaced with the organic film layer of the same structure.

Step 1203: The overlap region of the organic film layer is thinned so that an absolute value of a height difference between the overlap region of the processed organic film layer and other regions of the organic film layer is less than the thickness d.

After the organic film layer is formed on the substrate, the processed overlap region may be thinned so that an absolute value of a height difference between the overlap region of the processed organic film layer and other regions of the organic film layer is less than the thickness d. Reference may be made to FIG. 10 for the structure of the array substrate at the end of this step. At this time, the insulating film layer 130 in FIG. 10 is replaced with the organic film layer of the same structure.

Furthermore, as the organic film layer is able to be photo-etched, in addition to that the overlap region of the organic film layer may be thinned by etching, it is also possible to perform an exposure and development process to the overlap region of the organic film layer so that the absolute value of the height difference between the overlap region of the processed organic film layer and other regions of the organic film layer is less than the thickness d. Specifically, the height difference between the overlap region of the organic film layer and other regions of the organic film layer may be controlled by controlling the time of exposure. Alternatively, when the thickness of the organic film layer is greater than the thickness d, the height difference between the overlap region of the organic film layer and other regions of the organic film layer may be 0.

Step 1204: An insulating film layer is formed on the substrate on which the organic film layer is formed.

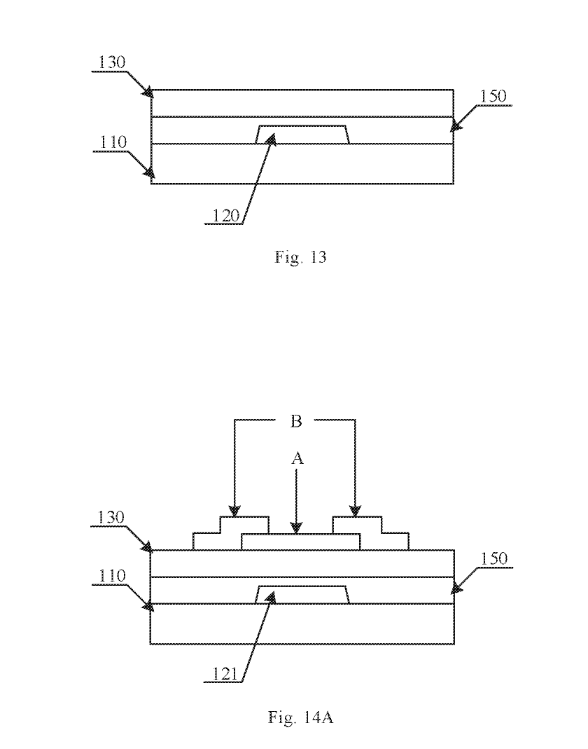

After the organic film layer is thinned, an insulating film layer may be formed on the substrate. As the absolute value of the height difference between the overlap region of the processed organic film layer and other regions of the organic film layer is less than the thickness d, the absolute value of the height difference between the overlap region of the insulating film layer formed on the organic film layer with the metal pattern and other regions of the insulating film layer is also less than the thickness d. FIG. 13 is a structural diagram of the substrate 110 with the insulating film layer 130 being formed on the organic film layer 150, wherein the metal pattern 120 is formed on the substrate 110.

Step 1205: A pattern of a semiconductor layer and a source/drain metal layer is formed on the substrate on which the insulating film layer is formed.

After the insulating film layer is formed on the substrate, a pattern of a semiconductor layer and a source/drain metal layer may be formed on the substrate, and then other subsequent processes are performed to the substrate. For the subsequent processes, reference may be specifically made to the prior art as required and they will not be described in detail here. The structure of sources/drains on the substrate is as shown in FIG. 14A. FIG. 14A is a structural diagram of the substrate 110 with the pattern B including the semiconductor layer A and sources/drains being formed on the insulating film layer 130, wherein the metal pattern is gate lines 121. The structure of data lines on the substrate is as shown in FIG. 14B. FIG. 14B is a structural diagram of the substrate 110 with data lines 140 being formed on the insulating film layer 130, wherein the metal pattern 120 is formed on the substrate 110.

In step 1202, for example, if an insulating organic film layer is formed, step 1204 may be omitted, that is, the insulating organic film layer serves as an insulating film layer. Then, the pattern of the semiconductor layer and the source/drain metal layer is formed on the substrate on which the insulating film layer is formed.

In conclusion, in the manufacturing method for an array substrate provided by this embodiment, by controlling the absolute value of the height difference between the overlap region of the insulating film layer and other regions of the insulating film layer to be less than the thickness d, the unevenness of other patterns subsequently formed on the substrate on which the insulating film layer is formed is correspondingly reduced, so that the effects of reducing the breakage possibility of a wiring formed on the insulating film layer and improving a rate of qualified product can be achieved.

FIG. 15 is a flowchart showing a manufacturing method for an array substrate according to another exemplary embodiment. The manufacturing method for an array substrate may include the following steps.

Step 1501: A metal pattern having a thickness d is formed on a substrate.

During manufacturing an array substrate, a metal pattern having a thickness d may be first formed on a substrate by a single patterning process. For example, 0.1 μm≦d≦0.4 μm. The metal pattern may be a pattern of gate lines, or a pattern of gate lines and common electrode wiring. The metal pattern may be made from Al, Cu, Mo or other metal. The substrate may be a glass substrate or other transparent substrate. Reference may be made to FIG. 8 for the structure of the substrate 110 at the end of step 1501.

It is to be noted that the metal pattern is generally a pattern including gate lines only; however, when it is required to use a metal electrode to improve the resistance homogenization of common electrodes, it is possible to provide additional metal wiring which are called common electrode wiring and located in a same layer as the gate lines, and a pattern of gate lines and common electrode wiring may be formed by a single patterning process.

Step 1502: A reverse pattern is formed on the substrate on which the metal pattern is formed, so that the reverse pattern is provided within a region without the metal pattern on the substrate, the reverse pattern being formed from an insulating material.

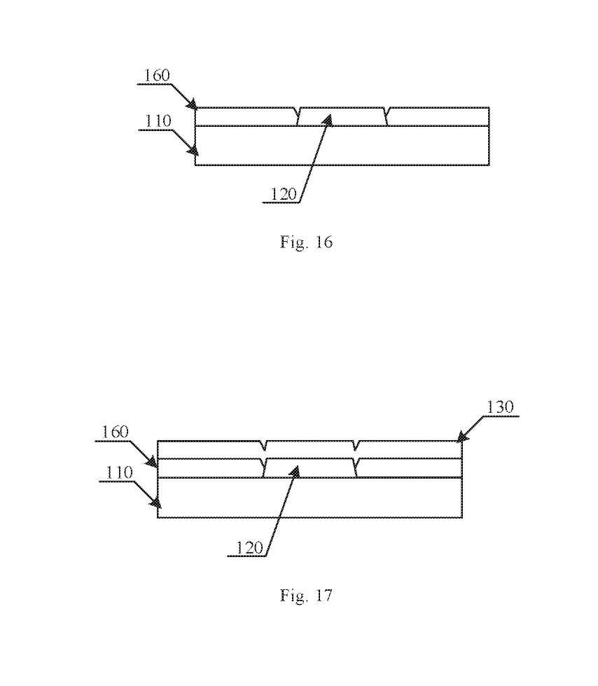

After the metal pattern is formed on the substrate, a region without the metal pattern on the substrate may be completely covered by an insulating material to allow the formed pattern is opposite to and completely complementary with the metal pattern. The formed pattern may be called a reverse pattern opposite to the metal pattern. The reverse pattern is provided within a region without the metal region on the substrate and made from the insulating material. Alternatively, the insulating material is an organic film or an insulating film. FIG. 16 is a structural diagram of the substrate 110 with the reverse pattern 160 being formed on the metal pattern 120. FIG. 16 shows a case where the thickness of the reverse pattern 160 is the same as that of the pattern of gate lines (i.e., the metal pattern 120).

It is to be noted that, the reverse pattern may be formed by a patterning process, so that the thickness of the reverse pattern is equal to that of the metal pattern 120, that is, the height difference between a region with the metal pattern 120 on the substrate and other regions may be 0.

Step 1503: An insulating film layer is formed on the substrate on which the reverse pattern is formed, so that the insulating film layer has an overlap region with the metal pattern, the absolute value of a height difference between the overlap region of the insulating film layer and other regions of the insulating film layer being less than the thickness d.

After the reverse pattern is formed on the substrate, an insulating film layer may be formed on the substrate, and the absolute value of a height difference between the overlap region of the insulating film layer and other regions of the insulating film layer is allowed to be less than the thickness d by controlling the height of the reverse pattern.

Alternatively, when the height of the reverse pattern is equal to that of the metal pattern, the height difference between the overlap region of the insulating film layer and other regions of the insulating film layer may be considered to be 0. FIG. 17 is a structural diagram of the substrate 110 with the insulating film layer 130 being formed on the reverse pattern 160, wherein the metal pattern 120 is formed on the substrate 110.

Step 1504: A pattern of a semiconductor layer and a source/drain metal layer is formed on the substrate on which the insulating film layer is formed.

After the insulating film layer is formed on the substrate, a pattern of a semiconductor layer and a source/drain metal layer may be formed on the substrate, and then other subsequent processes are performed to the substrate. For the subsequent processes, reference may be specifically made to the prior art as required and they will not be described in detail here. The structure of sources/drains on the substrate is as shown in FIG. 18A. FIG. 18A is a structural diagram of the substrate 110 with the pattern B including the semiconductor layer A and sources/drains being formed on the insulating film layer 130, wherein the metal pattern formed on the substrate 110 is a pattern 121 of gate lines. The structure of data lines on the substrate is as shown in FIG. 11. FIG. 11 is a structural diagram of the substrate 110 with data lines 140 being formed on the insulating film layer 130, wherein the metal pattern 120 is formed on the substrate 110.

In conclusion, in the manufacturing method for an array substrate provided by this embodiment, by controlling the absolute value of the height difference between the overlap region of the insulating film layer and other regions of the insulating film layer to be less than the thickness d, the unevenness of other patterns subsequently formed on the substrate on which the insulating film layer is formed is correspondingly reduced, so that the effects of reducing the breakage possibility of a wiring formed on the insulating film layer and improving a rate of qualified product can be achieved.

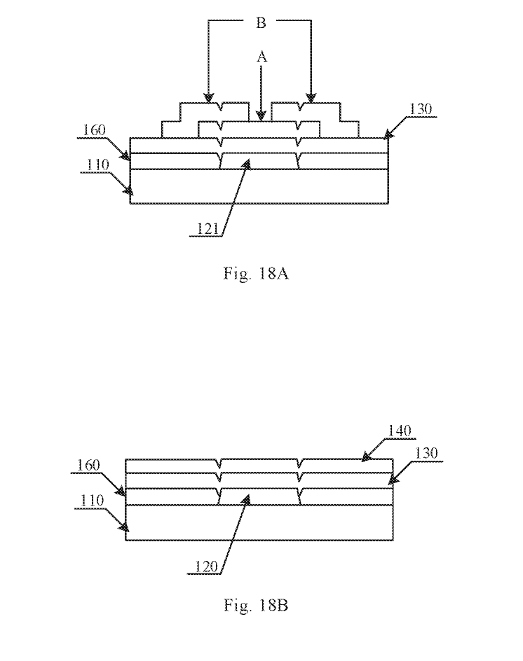

It is to be additionally noted that, FIG. 19A is a comparison diagram of a structure of sources/drains of an array substrate in the prior art and a structure of sources/drains in the array substrate provided by the embodiments of the present invention. Structure 1 is obtained by the manufacturing method for an array substrate shown in FIG. 2, structure 2 is obtained by the manufacturing method for an array substrate shown in FIG. 12, and structure 3 is obtained by the manufacturing method for an array substrate shown in FIG. 15. Similarly, FIG. 19B is a comparison diagram of a structure of sources/drains of an array substrate in the prior art and a structure of sources/drains in the array substrate provided by the embodiments of the present invention, wherein structure 1 is obtained by the manufacturing method for an array substrate shown in FIG. 2, structure 2 is obtained by the manufacturing method for an array substrate shown in FIG. 7, structure 3 is obtained by the manufacturing method for an array substrate shown in FIG. 12, and structure 4 is obtained by the manufacturing method for an array substrate shown in FIG. 15.

It can be clearly seen from FIGS. 19A and 19B that the manufacturing method for an array substrate provided by the embodiments of the prevent invention significantly reduces the protrusion of the overlap region of patterns of sources/drains and data lines.

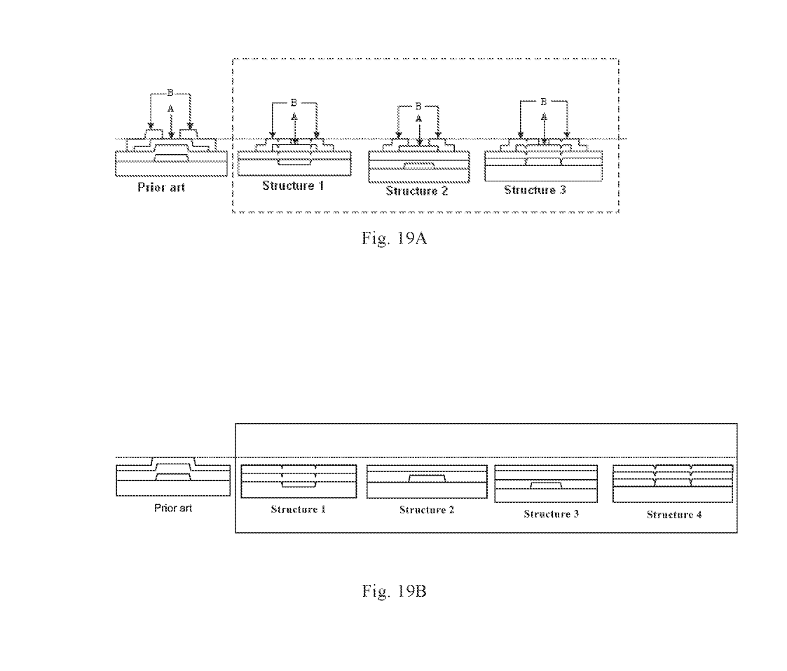

In addition, the four solutions provided in FIGS. 2, 7, 12 and 15 may also be implemented in combinations. For example, FIG. 20 is a flowchart showing a manufacturing method for an array substrate according to another exemplary embodiment. The manufacturing method for an array substrate may include the following steps.

Step 2001: A groove is formed on a substrate.

As shown in FIG. 3, during manufacturing an array substrate, a groove may be first formed on the substrate. The pattern of the groove may be the same as a metal pattern. The substrate may be a glass substrate or other transparent substrate.

Step 2002: A metal pattern having a thickness d is formed in the groove.

As shown in FIG. 4, the metal pattern having a thickness d is formed in the groove by a patterning process. For example, 0.1 μm≦d≦0.4 μm. The metal pattern may be a pattern including gate lines, or a pattern including gate lines and common electrode wiring. The metal pattern may be formed from Al, Cu, Mo or other metal.

It is to be noted that, when the depth of the groove is equal to the thickness d, the height difference between the overlap region of the subsequently formed insulating film layer and other regions of the insulating film layer may be considered to be 0. In this case, the influences of the metal pattern on sources/drains may be fundamentally eliminated.

Step 2003: A reverse pattern is formed on the substrate on which the metal pattern is formed, so that the reverse pattern is provided within a region without the metal pattern on the substrate, the reverse pattern being made from an insulating material.

When the height of the metal pattern formed on the groove is still higher than that of other regions without the metal patterns, a reverse pattern opposite to the metal pattern may be formed on the substrate, and the reverse pattern is provided within a region without the metal pattern on the substrate. The insulating material may be an organic material.

Step 2004: An initial insulating layer is formed on the substrate on which the reverse pattern is formed, wherein an overlap region of the initial insulating film layer with the metal pattern is protruded from the initial insulating film layer.

When the height of the metal pattern is still higher than that of the reverse pattern, an initial insulating film layer may be formed on the substrate on which the reverse pattern is formed. The overlap region of the initial insulating film layer and the metal pattern (e.g., gate lines) is protruded from the initial insulating film layer.

Step 2005: The overlap region of the initial insulating film layer is thinned to obtain an insulating film layer, so that an absolute value of a height difference between an overlap region of the insulating film layer and other regions of the insulating film layer is less than the thickness d.

After the initial insulating film layer is formed on the substrate, the overlap region of the initial insulating film layer may be thinned to obtain an insulating film layer, so that the absolute value of a height difference between an overlap region of the insulating film layer and other regions of the insulating film layer is less than the thickness d.

For example, the overlap region of the initial insulating film layer may be processed by a single patterning process so that the absolute value of the height difference between the processed overlap region of the insulating film layer and other regions of the insulating film layer is less than the thickness d. Specifically, the height difference between the overlap region of the insulating film layer and other regions of the initial insulating film layer may be controlled by controlling the time of etching. Alternatively, when the thickness of the initial insulating film layer is greater than the thickness d, the height difference between the processed overlap region of the insulating film layer and other regions of the insulating film layer may be 0.

Step 2006: A pattern of a semiconductor layer and a source/drain metal layer is formed on the substrate on which the insulating film layer is formed.

After the insulating film layer is formed on the substrate, a pattern of a semiconductor layer and a source/drain metal layer may be formed on the substrate, and then other subsequent processes are performed to the substrate. For the subsequent processes, reference may be made to the prior art as required and they will not be described in detail here.

It is to be noted that, the method embodiment is merely exemplary, and the manufacturing methods for an array substrate provided in FIGS. 2, 7, 12 and 15 may also have other combined technical solutions, which are limited in the present invention.

In conclusion, in the manufacturing method for an array substrate provided by this embodiment, by controlling the absolute value of the height difference between the overlap region of the insulating film layer and other regions of the insulating film layer to be less than the thickness d, the unevenness of other patterns subsequently formed on the substrate on which the insulating film layer is formed is correspondingly reduced, so that the effects of reducing the breakage possibility of a wiring formed on the insulating film layer and improving a rate of qualified product can be achieved.

Described below are product embodiments of the present invention, which may be products manufactured by the method embodiments of the present invention. For the details not disclosed in the product embodiments of the present invention, reference may be made to the method embodiments of the present invention.

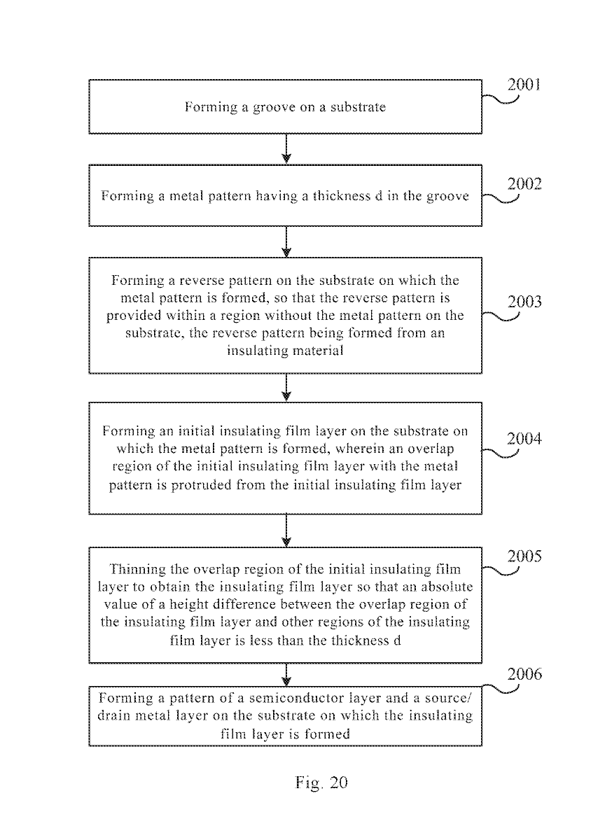

FIG. 21 is a structural diagram showing an array substrate according to an exemplary embodiment. The array substrate may include:

a substrate 110;

a metal pattern 120 having a thickness d formed on the substrate 110, wherein the metal pattern 120 may be a pattern including gate lines or a pattern including gate lines and common electrode wiring;

an insulating film layer 130 formed on the substrate 110 on which the metal pattern 120 is formed, wherein the insulating film layer 130 has an overlap region with the metal pattern 120, and an absolute value of a height difference x between the overlap region of the insulating film layer 130 and other regions of the insulating film layer 130 is less than the thickness d; and

a pattern C of a semiconductor layer A and a source/drain metal layer formed on the insulating film layer 130.

Alternatively, in the structure of another array substrate shown in FIG. 6A and FIG. 6B, a groove is formed on the substrate 110.

The metal pattern 120 having a thickness d is formed in the groove, and the insulating film layer 130 is formed on the substrate 110 on which the metal pattern 120 is formed. Both FIGS. 6A and 6B show a case where the depth of the groove is equal to the thickness of the metal pattern 120. In this case, the height difference between the overlap region of the insulating film layer 130 and other regions of the insulating film layer 130 is 0.

Alternatively, in the structure of another array substrate shown in FIG. 11, the insulating film layer 130 is obtained after thinning an overlap region of an initial insulating film layer formed on the substrate 110, which is formed with the metal pattern 120 thereon, with the metal pattern 120. Alternatively, the insulating film layer 130 is obtained after performing a single patterning process to the overlap region of the initial insulating film layer.

Alternatively, in the structure of another array substrate shown in FIGS. 14A and 14B, an organic film layer 150 is formed between the insulating film layer 130 and the substrate 110 on which the metal pattern 120 is formed, and the organic film layer 150 has an overlap region with the metal pattern 120. The insulating film layer 130 is generated on the organic film layer 150 after the overlap region of the organic film layer 150 is thinned. Alternatively, the insulating film layer 130 is generated on the organic film layer 150 after an exposure and development process is performed to the overlap region of the organic film layer 150.

Alternatively, in the structure of another array substrate shown in FIGS. 18A and 18B, a reverse pattern 160 is formed on the substrate 110 on which the metal pattern 120 is formed. The reverse pattern 160 is provided within a region without the metal pattern 120 on the substrate 110, and the reverse pattern 160 may be made from an insulating material. Then, an insulating film layer 130 is formed on the substrate 110 on which the reverse pattern 160 is formed, the insulating film layer 130 having an overlap region with the metal pattern 120, the absolute value of a height difference (not shown in FIGS. 18A and 18B) between the overlap region of the insulating film layer 130 and other regions of the insulating film layer 130 being less than the thickness d (not shown in FIGS. 18A and 18B). Alternatively, the insulating material may be an organic material.

Alternatively, in any one of the array substrates shown in FIGS. 21, 6A, 6B, 11, 14A, 14B, 18A and 18B, the height difference between the overlap region of the insulating film layer 130 with the metal pattern 120 and other regions of the insulating film layer 130 is 0.

It is to be noted that the array substrates shown in FIGS. 21, 6A, 6B, 11, 14A, 14B, 18A and 18B may further include necessary structures of other array substrates, and reference may be specifically made to the prior art as required and they will not be described in detail here.

In conclusion, in the array substrate provided by this embodiment, by controlling the absolute value of the height difference between the overlap region of the insulating film layer and other regions of the insulating film layer to be less than the thickness d, the unevenness of other patterns subsequently formed on the substrate on which the insulating film layer is formed is correspondingly reduced, so that the effects of reducing the breakage possibility of a wiring formed on the insulating film layer and improving a rate of qualified product can be achieved.

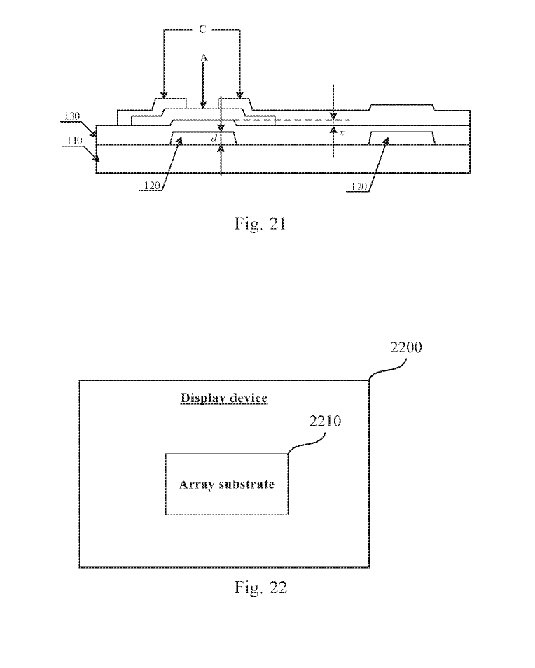

FIG. 22 shows a display device 2200 according to an exemplary embodiment. The display device 2200 may include any one of the array substrates 2210 shown in FIGS. 21, 6A, 6B, 11, 14A, 14B, 18A and 18B.

The foregoing embodiments are merely preferred embodiments of the present invention and not intended to limit the present invention. Any modification, equivalent replacement and improvement made within the spirit and principle of the present invention shall fall into the protection scope of the present invention.

1-23. (canceled)

24. A manufacturing method for an array substrate, comprising steps of:
forming a metal pattern having a thickness d on a substrate;
forming an insulating film layer on the substrate on which the metal pattern is formed so that the insulating film layer has an overlap region with the metal pattern, an absolute value of a height difference between the overlap region of the insulating film layer and other regions of the insulating film layer being less than the thickness d; and
forming a pattern of a semiconductor layer and a source/drain metal layer on the substrate on which the insulating film layer is formed.

25. The manufacturing method according to claim 24, wherein the step of forming a metal pattern having a thickness d on a substrate comprises steps of:
forming a groove on the substrate; and
forming the metal pattern having the thickness d in the groove.

26. The manufacturing method according to claim 24, wherein the step of forming an insulating film layer on the substrate on which the metal pattern is formed comprises steps of:
forming an initial insulating film layer on the substrate on which the metal pattern is formed, wherein an overlap region of the initial insulating film layer with the metal pattern is protruded from the initial insulating film layer; and
thinning the overlap region of the initial insulating film layer to obtain the insulating film layer so that the absolute value of the height difference between the overlap region of the insulating film layer and other regions of the insulating film layer is less than the thickness d.

27. The manufacturing method according to claim 26, wherein the step of thinning the overlap region comprises step of:
processing the overlap region of the initial insulating film layer by a single patterning process so that the absolute value of the height difference between the overlap region of the processed initial insulating film layer and other regions of the processed initial insulating film layer is less than the thickness d.

28. The manufacturing method according to claim 24, wherein the step of forming an insulating film layer on the substrate on which the metal pattern is formed comprises steps of:
forming an organic film layer on the substrate on which the metal pattern is formed, wherein the organic film layer has an overlap region with the metal pattern, and the overlap region of the organic film layer is protruded from the organic film layer;
thinning the overlap region of the organic film layer so that the absolute value of the height difference between the overlap region of the processed organic film layer and other regions of the processed organic film layer is less than the thickness d; and
forming the insulating film layer on the substrate on which the organic film layer is formed; or,
forming an insulating organic film layer on the substrate on which the metal pattern is formed, wherein the organic film layer has an overlap region with the metal pattern, and the overlap region of the organic film layer is protruded from the organic film layer; and
thinning the overlap region of the organic film layer so that the absolute value of the height difference between the overlap region of the processed organic film layer and other regions of the processed organic film layer is less than the thickness d.

29. The manufacturing method according to claim 28, wherein the step of thinning the overlap region of the organic film layer comprises step of:
performing an exposure and development process on the overlap region of the organic film layer so that the absolute value of the height difference between the overlap region of the processed organic film layer and other regions of the processed organic film layer is less than the thickness d.

30. The manufacturing method according to claim 24, wherein the step of forming an insulating layer on the substrate on which the metal pattern is formed comprises steps of:
forming a reverse pattern on the substrate on which the metal pattern is formed, so that the reverse pattern is provided within a region without the metal pattern on the substrate, the reverse pattern being formed from an insulating material; and
forming the insulating film layer on the substrate on which the reverse pattern is formed, so that the insulating film layer has an overlap region with the metal pattern, the absolute value of the height difference between the overlap region of the insulating film layer and other regions of the insulating film layer being less than the thickness d.

31. The manufacturing method according to claim 30, wherein the step of forming the insulating film layer on the substrate on which the reverse pattern is formed comprises steps of:
forming an initial insulating film layer on the substrate on which the reverse pattern is formed, wherein an overlap region of the initial insulating film layer with the metal pattern is protruded from the initial insulating film layer; and
thinning the overlap region of the initial insulating film layer to obtain the insulating film layer so that the absolute value of the height difference between the overlap region of the insulating film layer and other regions of the insulating film layer is less than the thickness d.

32. The manufacturing method according to claim 31, wherein the step of thinning the overlap region comprises step of:
processing the overlap region of the initial insulating film layer by a single patterning process so that the absolute value of the height difference between the overlap region of the processed initial insulating film layer and other regions of the processed initial insulating film layer is less than the thickness d.

33. The manufacturing method according to claim 30, wherein the step of forming an insulating film layer on the substrate on which the reverse pattern is formed comprises steps of:
forming an organic film layer on the substrate on which the reverse pattern is formed, wherein the organic film layer has an overlap region with the metal pattern, and the overlap region of the organic film layer is protruded from the organic film layer;
thinning the overlap region of the organic film layer so that the absolute value of the height difference between the overlap region of the processed organic film layer and other regions of the processed organic film layer is less than the thickness d; and
forming the insulating film layer on the substrate on which the organic film layer is formed; or,
forming an insulating organic film layer on the substrate on which the reverse pattern is formed, wherein the organic film layer has an overlap region with the metal pattern, and the overlap region of the organic film layer is protruded from the organic film layer; and
thinning the overlap region of the organic film layer so that the absolute value of the height difference between the overlap region of the processed organic film layer and other regions of the processed organic film layer is less than the thickness d.

34. The manufacturing method according to claim 33, wherein the step of thinning the overlap region of the organic film layer comprises step of:
performing an exposure and development process on the overlap region of the organic film layer so that the absolute value of the height difference between the overlap region of the processed organic film layer and other regions of the processed organic film layer is less than the thickness d.

35. The manufacturing method according to claim 24, wherein:
the metal pattern is a pattern comprising gate lines or a pattern comprising gate lines and common electrode wiring.

36. The manufacturing method according to claim 24, wherein:
the height difference between the overlap region of the insulating film layer and the other regions of the insulating film layer is 0.

37. An array substrate, comprising:
a substrate;
a metal pattern having a thickness d formed on the substrate;
an insulating film layer formed on the substrate on which the metal pattern is formed, wherein the insulating film layer has an overlap region with the metal pattern, and an absolute value of a height difference between the overlap region of the insulating film layer and other regions of the insulating film layer is less than the thickness d; and
a pattern of a semiconductor layer and a source/drain metal layer formed on the insulating film layer.

38. The array substrate according to claim 37, further comprising: a groove formed on the substrate, wherein the metal pattern having the thickness d is arranged in the groove.

39. The array substrate according to claim 37, further comprising an organic film layer formed between the insulating film layer and the metal pattern, wherein the organic film layer has an overlap region with the metal pattern.

40. The array substrate according to claim 37, further comprising a reverse pattern formed within a region without the metal pattern on the substrate, beneath the insulating film layer, wherein the reverse pattern is formed from an insulating material.

41. The array substrate according to claim 37, wherein:
the metal pattern is a pattern comprising gate lines or a pattern comprising gate lines and common electrode wiring.

42. The array substrate according to claim 37, wherein:
the height difference between the overlap region of the insulating film layer and other regions of the insulating film layer is 0.

43. A display device, comprising the array substrate according to claim 37.
